(19) United States
(12) Patent Application Publication
(10) Pub. No.: US 2017/0294327 A1
(43) Pub. Date: Oct. 12, 2017

(54) SUBSTRATE CONTAINER

(71) Applicant: ENTEGRIS, INC., Billerica, MA (US)

(72) Inventors: Barry GREGERSON, Deephaven, MN (US); Christian ANDERSEN, Carver, MN (US); Russ V. RASCHKE, Chanhassen, MN (US); Michael ZABKA, Eagan, MN (US)

(21) Appl. No.: 15/507,731

(22) PCT Filed: Aug. 28, 2015
(86) PCT No.: PCT/US2015/047498

§ 371 Date: Feb. 28, 2017

Related U.S. Application Data
(60) Provisional application No. 62/043,297, filed on Aug. 28, 2014.
(60) Provisional application No. 62/049,144, filed on Sep. 11, 2014.

(51) Int. Cl. H01L 21/673

(52) U.S. Cl. CPC H01L 21/67386; H01L 21/67383; H01L 21/67369; H01L 21/67366

(57) ABSTRACT

A front opening wafer container with a forward and rearward sets of stacked V-shaped wafer edge receiving portions, the rearward set part of a wafer shelf component and comprising a thin film of PBT preformed and overmolded with a polycarbonate. The sets of stacked V-shaped wafer edge receiving portions providing between-shelf seating positions above on-shelf seating positions. The PBT providing a low friction sliding engagement surface for the wafer edges thereby providing uniform and consistent dropping of wafers from the between shelf position to the on-shelf position when the door of the wafer container is removed.

### RELATED APPLICATIONS

This application claims priority to U.S. Provisional Application Nos. 62/043,297 filed Aug. 28, 2014, and 62/049,144 filed Sep. 11, 2014. Both applications are incorporated herein by reference in their entireties.

### FIELD OF THE DISCLOSURE

The present disclosure relates generally to wafer containers and to techniques for molding wafer containers and other substrate containers.

### BACKGROUND OF THE DISCLOSURE

The semiconductor industry introduces unique and unconventional purity and anti-contamination requirements into the development and implementation of product designs and manufacturing processes. Material selection is essential in the manufacturing, storage, and transportation of components and assemblies.

The processing of wafer disks into integrated circuit chips often involves several steps where the disks are repeatedly processed, stored and transported in wafer carriers including wafer containers. Due to the delicate nature of the disks and their extreme value, it is vital that they are properly protected throughout this procedure. One purpose of a wafer carrier is to provide this protection. Additionally, since the processing of wafer disks is generally automated, it is necessary for disks to be precisely positioned relative to the processing equipment for the robotic removal and insertion of the wafers. A second purpose of a wafer carrier is to securely hold the wafer disks during transport.

Wafer carriers are generally configured to axially arrange the wafers or disks in shelves or slots, and to support the wafers or disks by or near their peripheral edges. The wafers or disks are conventionally removable from the carriers in a radial direction upwardly or horizontally. Carriers may have supplemental top covers, bottom covers, or enclosures to enclose the wafers or disks. Although certain known wafer shippers may have only two parts, a base and a lid, front opening wafer containers for large wafers, 300 mm and 450 mm, may be quite complex with latch systems, separate shelves and externally mounted handling and machine interface components, ballast systems, sensors, and even environmental controls. And, of course, large wafers are much more expensive than smaller wafers requiring enhanced quality control and protection from damage.

Carriers and containers for substrate carriers, including wafer containers, are typically formed of injection molded plastics such as polycarbonate (PC), polyethylene (PE), perfluoroalkoxy (PFA), acrylonitrile butadiene styrene (ABS), polyether ether ketone (PEEK), polypropylene (PP) and others. There are a number of material characteristics which are useful and advantageous for wafer carriers depending on the type of carrier and the particular part or component of the carrier at issue. Such characteristics include the cost of the material and the ease or difficulty in molding the material. Various issues associated with semiconductor manufacturing as they related to material characteristics are discussed below. Often a certain polymer will be used for one component and another polymer for a different component. Or a component may be made of two or more polymers.

During processing of semiconductor wafers or magnetic disks, the presence or generation of particulates presents very significant contamination problems. Contamination is accepted as the single largest cause of yield loss in the semiconductor industry. As the size of integrated circuitry has continued to be reduced, the size of particles which can contaminate an integrated circuit has also become smaller, making minimization of contaminants all the more critical. Contaminants in the form of particles may be generated by abrasion such as the rubbing or scraping of the carrier with the wafers or disks, with the carrier covers or enclosures, with storage racks, with other carriers, or with the processing equipment. A most desirable characteristic of a carrier is therefore a resistance to particle generation upon abrasion, rubbing, or scraping of the plastic molded material. See U.S. Pat. No. 5,780,127, owned by a corporate predecessor of the owner of the instant application. The patent discusses various characteristics of plastics which are pertinent to the suitability of such materials for wafer carriers. Said patent is incorporated herein by reference for all purposes.

Carrier materials should also have minimal outgassing of volatile components as these may leave films which also constitute a contaminant which can damage wafers and disks. Polymer materials that release contaminants are known as “dirty” materials and usage within enclosed wafer containment environments causes contamination issues. One such material is polybutylene terephthalate (PBT) and thus usage of such has been limited in wafer carriers, particularly wafer containers.

Also, carrier materials must have adequate dimensional stability, that is, rigidity, when the carrier is loaded. Dimensional stability is necessary to prevent damage to the wafers or disks and to minimize movement of the wafers or disks within the carrier. The tolerances of the slots holding wafers and disks are typically quite small and any deformation of the carrier can directly damage the highly brittle wafers or increase the abrasion and thus the particle generation when the wafers or disks are moved into, out of, or within the carrier. Dimensional stability is also extremely important when the carrier is loaded in some direction such as when the carriers are stacked during shipment or when the carriers integrate with processing equipment. The carrier material should also maintain its integrity under elevated temperatures which may be encountered during storage or cleaning.

Visibility of wafers within closed containers is considered desirable in many cases and may be required by end users. Transparent plastics suitable for such containers, such as polycarbonates, are desirable in that such plastic is low in cost but such plastics may not have sufficient performance characteristics such as abrasion resistance, heat resistance, chemical resistance, outgassing containment, rigidity characteristics, creep reduction, fluid absorption containment, UV protection, and the like.

One major benefit of particular specialized polymers, such as PEEK, is their abrasion-resistant qualities. Typical inexpensive conventional plastics release tiny particles into the air when abraded or even when rubbed against other material or objects. While these particles are typically invisible to the naked eye, they result in the introduction of potentially damaging contaminants that may adhere to semiconductor components being processed, and into the necessarily controlled environments. Such specialized thermoplastic polymers are dramatically more expensive than conventional polymers.

As a result, overmolding has been adopted by manufacturers of substrate containers, specifically wafer containers, where two distinct portions, each injection molded and each formed of different polymers are made intergral during the overmolding such that there is a gapless, crackless, hermetic juncture between the two different polymers. See U.S. Pat. Nos., 6,428,729; 6,428,729; and 7,168,564 which are owned by the owner of the instant application. These patents are incorporated herein by reference for all purposes. In certain circumstances it has been found that stresses may be associated with the overmolded component, especially where there are significant expanses of the polymers, such as in container portions. These stresses make fracturing under shock situations more common. It would be helpful to have a solution to the fracturing issue.

Moreover, it is expensive to manufacture the different mold components for overmolding when both (or more) portions are injection molded. Additionally, see U.S. Pat. Publications US20050236110, and US20050056601 in which thin film molding was disclosed in an overmold application. These publications are incorporated by reference herein for all purposes. The thin films have some minimal rigidity such that inserting them in three dimensional complicated structure is problematic. The techniques disclosed in said publications have not been commercially adopted for various reasons, presumably due to their difficulty in actual use and including the difficulty of repeatedly molding a consistent product using thin films.

As mentioned above, it is critical for wafers to be properly positioned in wafer carriers so that they are properly grasped and not damaged by robotic handling equipment. It has been found that during the door removal of 300 mm wafer containers, such as FOSBS(“Front Opening Shipping Boxes”), wafers drop inconsistently from a between-shelf seating position to an on-shelf seating position. In other words, the wafers are not uniformly positioned on the shelves. A solution to this problem would be welcome.

Overcoming the disadvantages of overmolding thin films and finding advantageous applications for thin film molding would be welcomed by the industry.

### SUMMARY OF THE DISCLOSURE

Embodiments of the present disclosure relates generally to a system and method for including a thin protective containment thermopolymer film in the molding process for handlers, transporters, carriers, trays and like devices utilized in the semiconductor processing industry. The thermoplastic film of suitable size and shape may be vacuum formed into a preform that approximates the final shape of the component portion desired. The shaped preform is then put in the component mold, and overmolded with the primary injection molded polymer. In embodiments, pins, or other structure may secure the thin film in position so that the polymer being injected does not displace or move the pre-shaped thin film. Suitable texturing may be provided with the thin film before insertion in the component mold or the mold may have surface treatment to modify the thin film surface texture in the final molded component.

In embodiments, a thin strip of PBT is pre-shaped by heating the strip with a suitable form to shape the wafer engagement ramp surfaces at the back side of a wafer container. The preformed strip, the “preform”, is then put in a mold that includes wafer shelves and the ramp surfaces and conventional polycarbonate is injection molded over the preformed strip. In embodiments, the PBT thin film may be 0.254 mm thick or within a range of plus or minus 25% of the 0.254 mm. The PBT allows the wafers to easily slide down from the seated position in the valley of V-shaped recess to seat on shelves as is conventional in front opening shipping boxes (FOSBs).

In other embodiments the PBT film may be about 0.254 mm. In other embodiments the PBT thin film may be 0.254 mm±0.050 mm. In other embodiments the PBT thin film may be 0.100 to 0.400 mm thick. In other embodiments the PBT thin film may be less than 0.300mm. In other embodiments the PBT thin film may be, less than 0.500 mm. In other embodiments the PBT thin film may be less than 1 mm. The above ranges also may be applicable for other thin films such as PEEK, PTFE, PFA, PC, amongst others. Such films may be formed of combinations of polymers and have additives.

A feature and advantage of some embodiments is that a conventional mold originally used for non-overmolding applications, can be used for overmolding applications without a new mold being constructed for the first portion of the overmold. Rather a less precise form, such as a form for vacuum form molding of thin components may be utilized for forming the preform. Such forms are significantly less expensive than injection molds.

In embodiments, pins or claws or other structure may retain the preformed film in place before and during the injection molding of the polymer over same.

In embodiments, an original mold may be sufficiently heated to preform the thin film before the primary molding operation; “primary” in the sense of greater quantities such as when the polycarbonate is injected for the base.

In embodiments, the component mold may have gates for injecting the molten polymer in the cavity directly opposite the seated position of the thin film portion for providing improved retention of the thin film in the mold. Where the desired location of the thin film for functionality is displaced from injection gates, the thin film insert portion may be enlarged to position a portion of the thin film opposite the gate for better securement of the thin film.

In embodiments, a mold may have a gate placed opposite where the thin film will be placed and have supplemental pins, hooks, or other hold-down features.

In embodiments, the thin film may be pre-formed for wafer engagement surfaces, reticle engagement surfaces, machine interface engagement surfaces, other contact surfaces. In embodiments a thin film may be preshaped, to define a containment surface, thereby providing a barrier to prevent outgassing or diffusion of moisture out of the primary containment material, which may be for example PC.

A feature and advantage of particular embodiments is that they provide a cost-efficient method of selectively utilizing desirable polymers, and the polymers' corresponding functional characteristic, wherein it is not necessary to utilize more of the polymer than is required.

Another advantage and feature of particular embodiments is that a functional thermoplastic film can be selectively bonded to a portion of a wafer carrier, chip tray, or other semiconductor component handler or transporter that contacts sensitive parts, components, or processing equipment.

A further advantage and feature of particular embodiments is the selective use of preferred low friction and/or abrasion-resistant polymer films on parts being used in the semiconductor processing industry for engagement of functional portions of substrate contacting surfaces.

Still another advantage and feature of particular embodiments is forming a semiconductor component handling device with a polymer filmed surface area that is transparent or translucent while still providing functional performance advancements for the selected surface. Such a handling device is formed by utilizing a thin enough layer of a material on a selected target structure of the device, preforming the layer, and overmolding the structure, to the substantially transparent or translucent device body constructed of a material such as PC.

A feature and advantage of embodiments is utilization of a preformed thin film intermediate injection molded overmolded portions. In such applications, the thin film may be preformed to be applied to the first injection molded portion and the second injection molded portion is molded thereon.

A feature and advantage of embodiments is a front opening wafer container that has a between-shelf seating position for wafers defined by forward and rearward V-shaped wafer edge receiving portions and an on-shelf seating position and that utilizes a material in the rearward V-shaped wafer edge receiving portion that has a coefficient of friction with respect to the wafers that is less than the material utilized for the forward V-shaped wafer edge receiving portions. Whereby when the door is removed from the front opening wafer container, the wafers drop from the between-shelf seating position to the on-shelf seating position more uniformly and have less of a tendency to not seat properly. In such embodiments, the material of the rearward V-shaped wafer edge receiving portion may be PBT and the material of the forward V-shaped wafer edge receiving portions may be polycarbonate or other material that presents a frictional resistance to wafers sliding on the ramps of the V-shaped wafer edge receiving portions.

A feature and advantage to embodiments ‘herein is that upon opening the doors to 300 mm wafer containers incorporating the disclosure, the wafers drop and seat more uniformly upon the wafer shelves compared to prior art wafer containers. A feature and advantage of embodiments of the disclosure is utilizing PBT for wafer seating portions without exposing the wafers to unacceptable levels of contaminants from the PBT.

### BRIEF DESCRIPTION OF THE DRAWINGS

FIG. 1 is a perspective view of a front opening wafer container according to embodiments of the disclosure.

FIG. 2 is a front perspective view of a container portion of the wafer container of FIG. 1.

FIG. 3 is a partial exploded view of the container portion of FIG. 2 with the wafer shelf component removed.

FIG. 4 is a perspective view of the inside surface and side walls of the door of FIG. 1.

FIG. 5 is a side cross-sectional view of portions of a wafer container and illustrating the on-shelf seating position of a wafer with the door not in place according to an embodiment of the invention.

FIG. 6 is a side cross-sectional view of portions of the wafer container of FIG. 5 after the door has been placed and received by the container portion and illustrating the raising of the wafer to the between-shelf position with the door closed according to an embodiment of the invention.

FIG. 7 is a side cross-sectional view of portions of the wafer container of FIGS. 5 and 6 with the wafer container rotated whereby wafers in the container are oriented vertically for shipment according to an embodiment of the invention.

FIG. 8 is a perspective view of a polycarbonate wafer shelves with a pre-formed wafer engagement film overmolded with the polycarbonate according to an embodiment of the invention.

FIG. 9A is an elevational view of thin film strip suitable for a preform according to an embodiment of the invention.

FIG. 9B is an elevational view of a preformed thin film according to an embodiment of the invention.

FIG. 10 is an elevational view of a preformed thin film strip with taps extending from a functional portion of the strip for hold down purposes in the mold according to an embodiment of the invention.

FIG. 11 is a close up view of the wafer shelf component of FIG. 8 illustrating the insert strip (shown stippled) overmolded with polycarbonate according to an embodiment of the invention.

FIG. 12 is a close up view of the wafer shelf component of FIGS. 8 and 11 illustrating the V-shaped wafer receiving portions of the insert strip (shown stippled) overmolded with polycarbonate according to an embodiment of the invention.

FIG. 13 is a perspective view of a wafer receiving stacked ramp component suitable for attachment to a door or the back side of a wafer container according to an embodiment of the invention.

FIG. 14 is a cross-sectional view of a wafer shelf component mold piece illustrating a placement position for a preform according to an embodiment of the invention.

FIG. 15 is a cross-sectional view of a wafer shelf component mold having a clamping member according to an embodiment of the invention.

FIG. 16 is a cross-sectional view the mold of FIG. 15 with the clamping member securing the preform and with molten polymer being injected therein according to an embodiment of the invention.

FIG. 17 is a cross-sectional view the mold of FIG. 15 with the clamping member securing the preform and with molten polymer having been injected therein according to an embodiment of the invention.

FIG. 18 is a cross-sectional view the mold of FIG. 15 with the clamping member being retracted according to an embodiment of the invention.

FIG. 19 is a cross-sectional view the mold of FIG. 15 with the clamping member retracted and the polymer filing in the region previously displaced by the clamping member according to an embodiment of the invention.

FIG. 20 is a cross-sectional view of a wafer shelf component mold illustrating a placement position for a preform and an injection molding gate positioned in the cavity opposite from the placement position according to an embodiment of the invention.

FIG. 21 is a cross-sectional view of a wafer shelf component mold of FIG. 20 illustrating injection molding flow dynamics of the molten polymer according to an embodiment of the invention.

### DETAILED DESCRIPTION

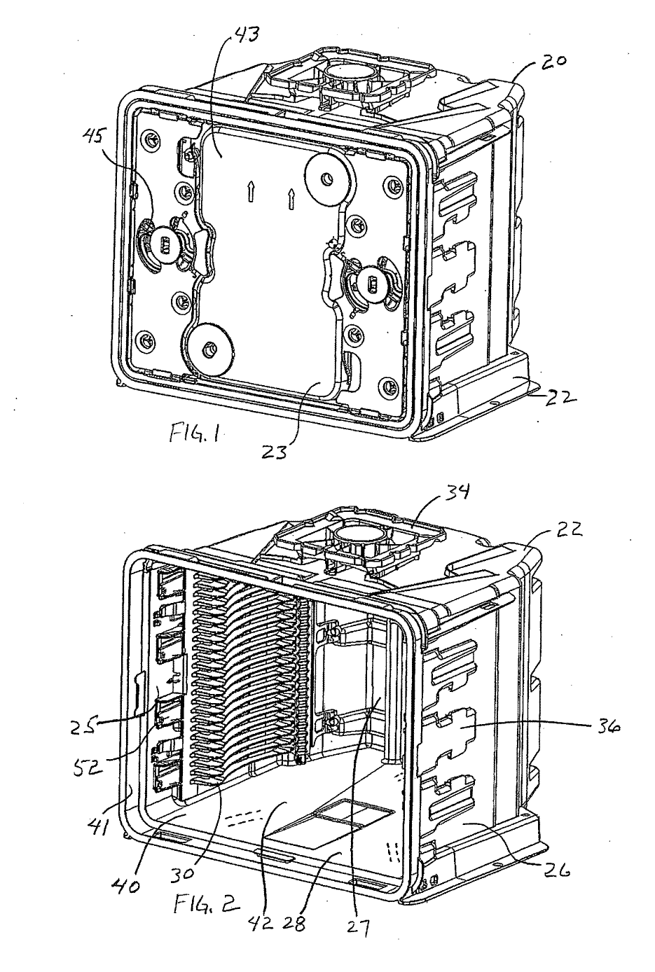

Referring to FIGS. 1-4, a front opening wafer container 20 comprises a container portion 22 and door 23 suitable for 300 mm 450 mm wafers 24. The container portion has left and right side walls 25, 26, a back wall 27, a bottom wall 28, a pair of wafer shelf components 30, a kinematic coupling 32 attached to the bottom wall, a robotic flange 34, and manual handle attachment structure 36. Wafers 24 are received through the open front 40 defined by the door frame 41 leading into the open interior 42.

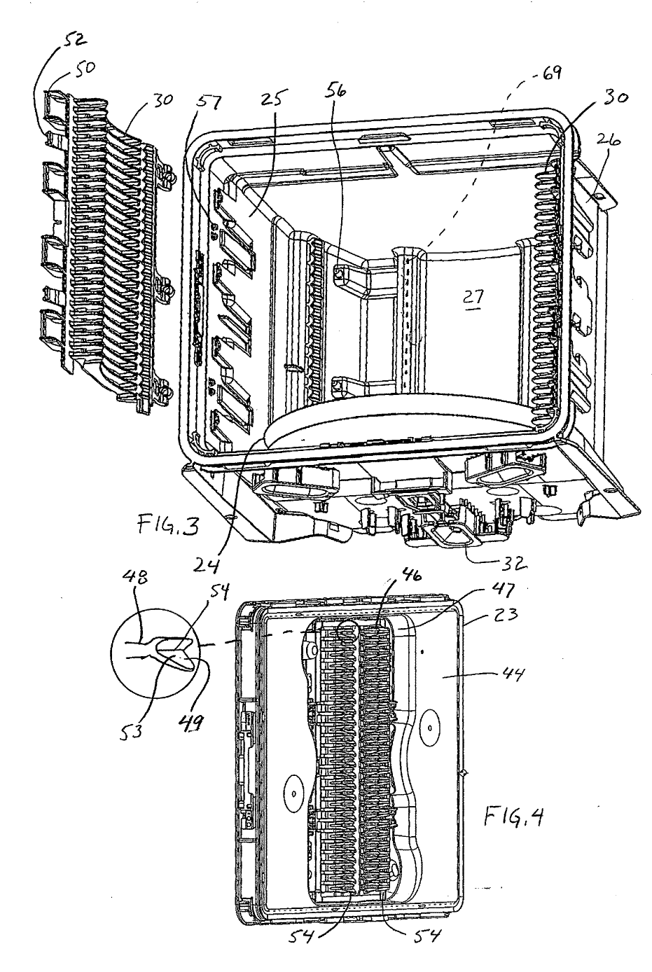

Referring to FIGS. 1 and 4, the door 23 has a front side 43, a back side 44, a latch mechanism 45 accessible on the front side, and a wafer cushion component 46 attached at a recess 47 on the back side. The wafer engagement component has a plurality fingers 48, each with a V-shaped wafer edge receiving portion 49 with a ramp 53 for engaging a edge of a wafer, and a seating position 54 at the apex The fingers with the ramps form two sets of stacked ramps 55.

Referring to FIGS. 1-4 and 8-13, the wafer shelf component 30 may be attached to the sidewalls 25, 26 by way of connectors 50 and latches 52 that attach to features such as lugs 56 and nubs 57 on the sidewalls 25, 26 of the container portion (FIG. 3). The wafer shelf component 30 has a plurality of wafer shelves 60 with wafer seating ridges 62 extending transverse to the lengthwise dimension of the shelves 60. The wafer shelf component in embodiments has a plurality of. V-shaped wafer edge receiving portions 64 each with a ramp 65 (FIG. 12) forming a vertical set of stacked ramps 66. Each V-shaped wafer receiving portion 64 has a wafer edge seating position 67 at the apex of a V-shaped recess 68 (FIG. 11). Referring to FIG. 13, in some embodiments the set of stacked ramps 66 may be a stacked ramp component 70 separate from the shelves 60 and shelf component 30 may be attached to the back wall 27 such as at the location illustrated by the dashed lines 69 in FIG. 3. Alternatively, such a component may also be mounted on the inside or back side of the door 23 in lieu of the stacked ramps provided by the discrete wafer fingers 48 (FIG. 4). The component 70 may attach by conventional means such as press fitting tabs 71 with apertures onto nubs on the door or on the container portion or by means similar to the means for attaching the wafer shelf component described herein.

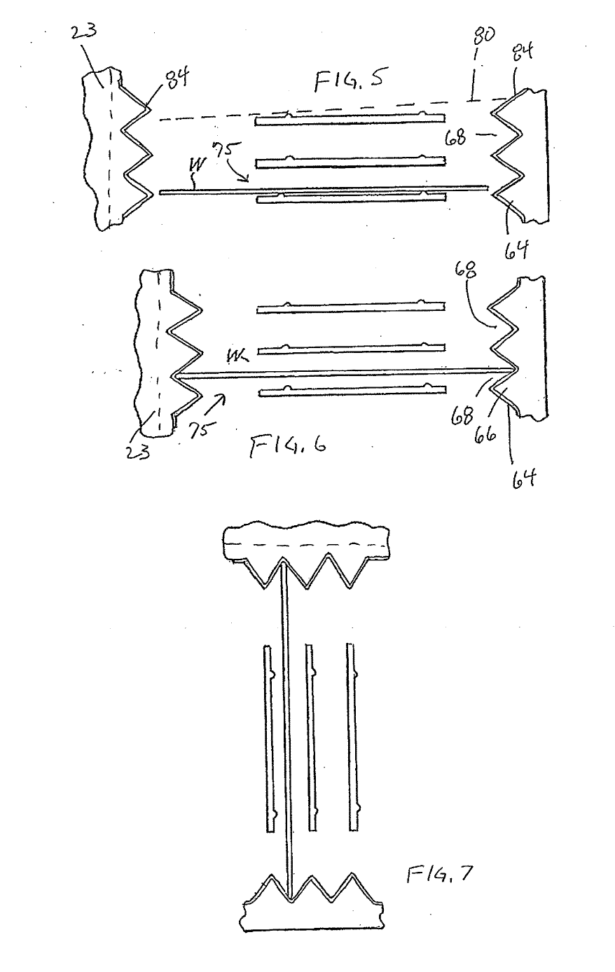

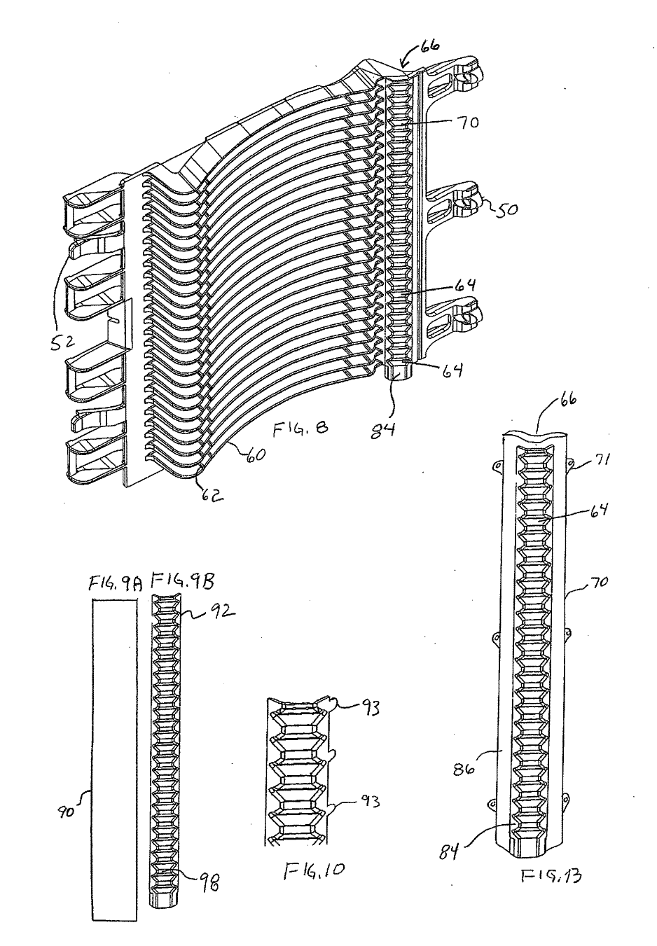

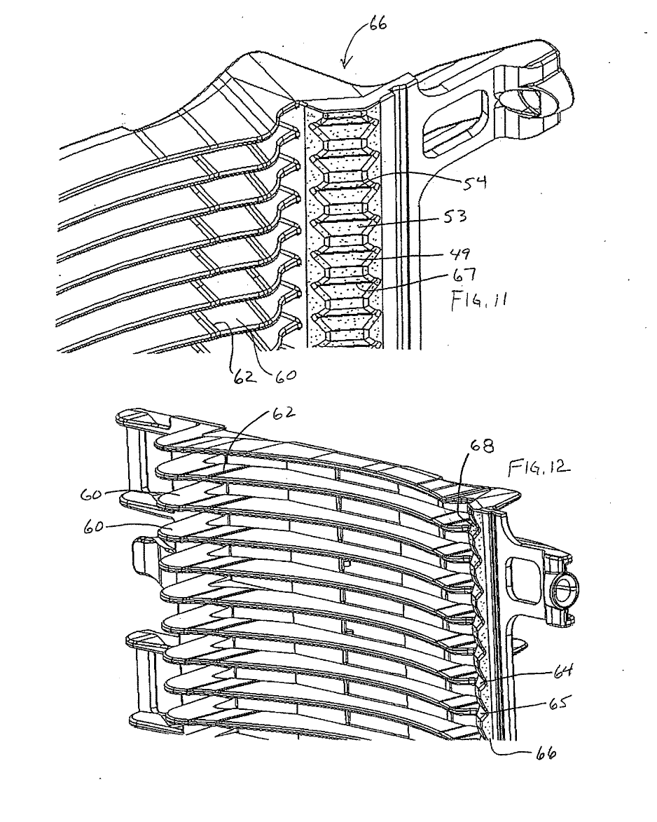

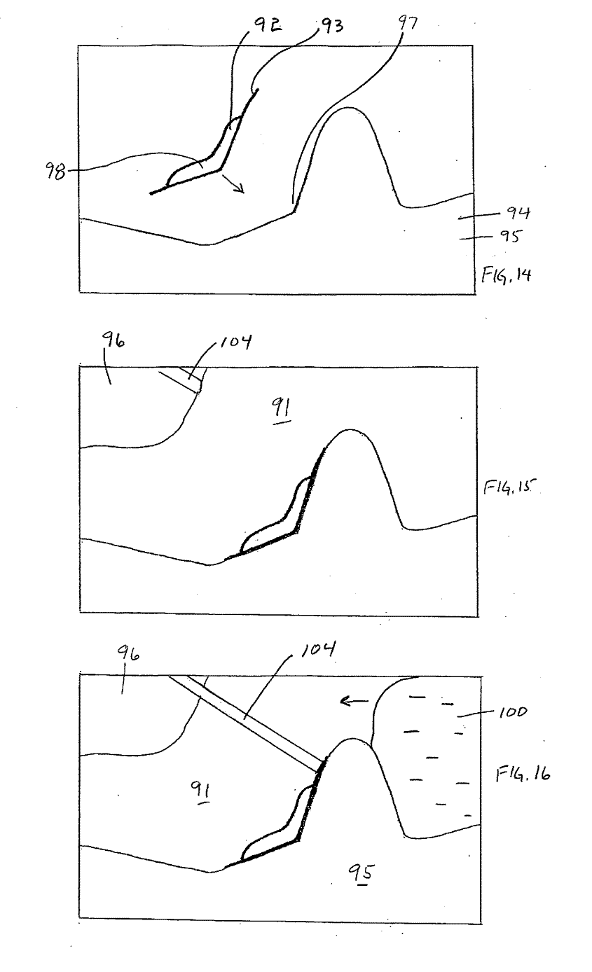

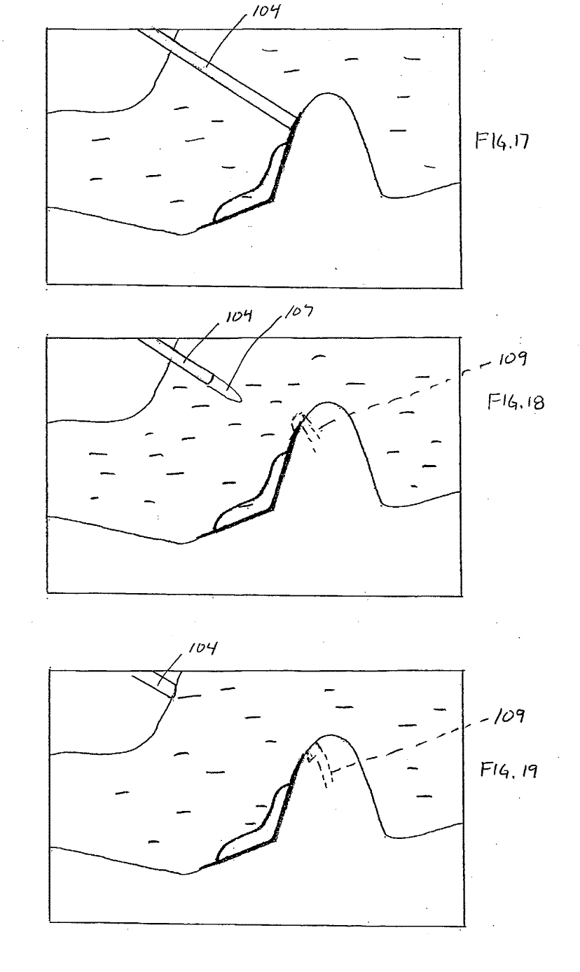

Referring to FIGS. 5, 6, and 7, when the door 23 closes the open front 40 with wafers 24 on the shelves 60, the wafers ride up the ramps 76 from a “on-shelf” seating position 75 to seat in the apex of the V-shaped recess 68 in a “ between-shelves” seating position 77. When the door 23 is removed the wafers slide down to again seat on the shelves. See U.S. Pat. No. 6,267,245, owned by the owner of the instant application and incorporated herein by reference for all purposes. The inventors have found that ramps formed of polycarbonate, a common material used in wafer containers, have a high coefficient of friction and the wafers may fail to fully drop to the shelf as the door is removed, as is illustrated by the dashed line 80 in FIG. 5. An effective solution has been to utilize PBT as the wafer edge contact surface which has been found to substantially eliminate the issue of wafers failing to fully drop to the shelves upon removal of the door. The stack of wafer edge receiving portions 64 as illustrated comprises a strip 84 of PBT that is provided by overmolding. The strip is bonded to a PC base portion 86. In other embodiments, the door 23 may include a non-PBT wafer cushion with a non-PBT wafer engagement surface. Where the set of stacked ramps is defined by discrete fingers 48 which deflect under loading (FIG. 4), the higher coefficient of friction of the polycarbonate or other polymers compared to PBT is not as much of a factor. Moreover, as the door is moved away, the wafer will necessarily fall from at least one of the front or back V-shaped wafer receiving portions and then engage the shelf. The shelf will then “grip” the wafer such that it will necessarily release from the door. Use of the PBT strip has been found to provide uniform and consistent release characteristics of the wafers from the between-shelves seating position to the on-shelf seating position. Notably, it is known that PBT can release contaminants, although it has been found that the quantities utilized in this application, do not appreciably increase contamination issues. So the thin file strips herein that are suitable for use are less than an inch in width and less than 14 inches in length.

In embodiments, the PBT thin film may be 0.254 mm thick or within a range of plus or minus 25%. In other embodiments, the PBT thin film may be 254 mm±0.050 mm thick. In other embodiments the PBT thin film may be 0.100 to 0.400 mm thick. In other embodiments the PBT thin film may be less than 0.300 mm. In other embodiments the PBT thin film may be less than 0.500 mm. In other embodiments the PBT thin film may be less than 1 mm. The above ranges also may be applicable for other thin films such as PEEK, PTFE, PFA, PC, amongst others. Such films may be formed of combinations of polymers and have additives.

Referring to FIGS. 9A-9B and 14-19, a sequence of overmolding is illustrated according to embodiments of the disclosure. The flat strip 90 of FIG. 9A is subjected to a preform such as by vacuum molding as illustrated by various known vacuum molding means, for example as described in U.S. Pat. No. 3,041,669. Said reference is incorporated by reference herein for all purposes. The preform is configured as a preformed strip 92, as illustrated in FIG. 9B. The preform has an approximation or better of the final mold shape and configuration such that it seats within a mold 94 (FIG. 14). The preform is placed in the appropriate placement position 97 in a mold 94 which reflects the location of the stacked ramps 66 of the wafer shelf component 30. The mold is closed as shown in FIG. 15 such that a cavity 91 reflecting the final part shape is defined by the respective first and second mold parts 95, 96.

Suitable texturing may be provided with the thin film before insertion in the component mold or the mold may have surface treatment to modify the thin film surface texture in the final molded component.

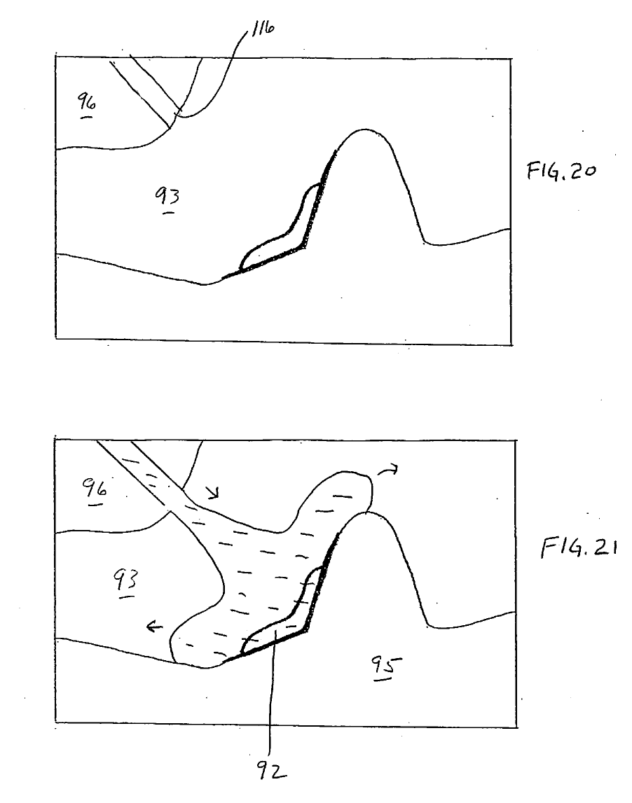

The preform 92 may have retention portions 93, such as tabs, that are displaced from the functional portion 98 of the preform, that is displaced from the ramps and V-shaped engagement portions. The retention portions may be gripped or clamped in the mold 94, see FIGS. 15 and 16, by a clamping member 104, configured as a pin, so that the preform is retained in place during the flow of the molten polymer 100 during the injection molding process. Several such clamping members may be used and are ideally positioned on the “upstream” side of the preform part as seen in FIG. 16. After the mold cavity is has been filled (FIG. 17), such that the molten polymer is not flowing, or has substantially stopped flowing, the clamping member 104 is retracted (FIG. 18) The polymer may then backfill into the region 107 previously displaced by the clamping member 104. Other configurations of clamping members may be utilized such as a hook piece 109 operative in the first mold piece 95 as illustrated by the dashed lines in FIGS. 18 and 19.

In addition to insert molding a single film, a plurality of films can be laminated to form a composite film structure for moldable bonding to the semiconductor component handling devices. For instance, various film layers can include differing performance or containment characteristics listed herein, or to provide a combination thereof. A myriad of film lamination techniques known to one skilled in the film lamination art are envisioned for use with embodiments of the disclosure. For instance, U.S. Pat. Nos. 3,660,200, 4,605,591, 5,194,327, 5,344,703, and 5,811,197 disclose thermoplastic lamination techniques and are incorporated herein by reference in their entireties for all purposes.

Referring to FIGS. 20 and 21, another molding methodology is illustrated for retention of the preform in place. The preform 92 is placed in the placement position 97 as in the above methodology. The second mold piece includes a gate 116 for injection of the molten polymer and the gate is positioned at the mold cavity directly opposite the preform placement position 97. The force of the moving molten polymer driving against the preform effectively secures the preform in place on the first mold piece. The arrows indicate the flow directions of the molten polymer. Other known techniques may also be utilized to secure the preform in place.

The above references in all sections of this application are herein incorporated by references in their entirety for all purposes.

All of the features disclosed in this specification (including the references incorporated by reference, including any accompanying claims, abstract and drawings), and/or all of the steps of any method or process so disclosed, may be combined in any combination, except combinations where at least some of such features and/or steps are mutually exclusive.

Each feature disclosed in this specification (including references incorporated by reference, any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The disclosure is not restricted to the details of the foregoing embodiment (s). The disclosure extends to any novel one, or any novel combination, of the features disclosed in this specification (including any incorporated by reference references, any accompanying claims, abstract and drawings), or to any novel one, or any novel combination, of the steps of any method or process so disclosed The above references in all sections of this application are herein incorporated by references in their entirety for all purposes.

Although specific examples have been illustrated and described herein, it will be appreciated by those of ordinary skill in the art that any arrangement calculated to achieve the same purpose could be substituted for the specific examples shown. This application is intended to cover adaptations or variations of the present subject matter. Therefore, it is intended that the disclosure be defined by the attached claims and their legal equivalents, as well as the following illustrative aspects. The above described aspects embodiments of the disclosure are merely descriptive of its principles and are not to be considered limiting. Further modifications of the disclosure herein disclosed will occur to those skilled in the respective arts and all such modifications are deemed to be within the scope of the disclosure.

1-23. (canceled)

24. A connector fitting for fluid handling comprising:
a coupling leg defining a bore that extends therethrough, said coupling leg and said bore being concentric about a leg axis, said coupling leg including a neck portion, a shoulder portion extending distal to said neck portion, a threaded portion extending distal to said shoulder portion, and a nipple portion extending distal to said threaded portion, said neck portion including locking features extending radially outward therefrom; and
a nut threadably engaged with said threaded portion of the coupling leg,
wherein said coupling leg and said nut are made of a melt processible resin.

25. The connector fitting of claim 1, wherein said locking features include a plurality of protrusions that are distributed about said leg axis at uniform angular intervals.

26. The connector fitting of claim 2, wherein said locking features include a flange portion concentric about the respective leg axis and extending radially outward from the neck portion.

27. The connector fitting of claim 26, wherein each of said plurality of protrusions extend distally from said flange portion and proximally from said shoulder portion.

28. The connector fitting of claims 25, wherein each of said plurality of protrusions include opposing flat sides that face tangentially about said leg axis and a flat top that faces radially outward from said leg axis.

29. The connector fitting of claim 24, wherein said locking features include a flange extending radially outward from said neck portion and a plurality of partitions extending distally from said flange, said flange and said plurality of partitions cooperating to define a plurality of pockets.

30. The connector fitting of claim 29, comprising a locking ring that defines and is concentric about a locking ring axis, said locking ring including an inner surface that includes one or more tabs that project radially inward toward said locking ring axis, said one or more tabs being configured to mate within one or more of said plurality of pockets.

31. The connector fitting of claim 30, wherein said one or more tabs of said locking ring are disposed within said one or more of said plurality of pockets of said neck portion, said partitions contacting with said one or more tabs to limit said locking ring to a within a range of rotation about said locking ring axis relative to said neck portion.

32. The connector fitting of claim 31, wherein said range of rotation is less than 15 degrees.

33. The connector fitting of claim 24, wherein said locking features include a plurality of spacers on opposing sides of the neck portion, said spacers extending orthogonal to said leg axis and including first and second opposing ends, wherein said first opposing ends of said plurality of spacers define a first plane, and said second opposing ends of said plurality of spacers define a second plane, said first plane and said second plane being parallel to each other and on opposing sides of said coupling leg.

34. A wrench for tightening the connector fitting of claim 25, the wrench comprising:
a first head having a body portion;
a first leg and a second leg extending in opposing directions from said body portion;
a first tooth that cooperates with the first leg to define a first notch on the first leg;
a second tooth that cooperates with the body portion to define a second notch on said body portion; and
an end boss defined at a distal end of said second leg,
wherein said first notch, said second notch, and said end boss are centered about a rotation axis.

35. The wrench of claim 34, comprising a handle portion, wherein said first head is disposed at a first end of said handle portion, said handle portion defining a handle axis.

36. The wrench of claim 11, comprising a second head at a second end of said handle portion, said second head including an arcuate spanner portion having an inside surface, a plurality of teeth protruding from said inside surface.

37. A method of installing the connector fitting of claim 25, comprising:
providing at least one wrench;
providing a set of installation instructions, said installation instructions comprising:
securing said connector fitting by bringing said first notch of the wrench into contact with a first of said plurality of protrusions, said second notch into contact with a second of said plurality of protrusions, and said boss end into contact with a third of said plurality of notches; and
tightening said nut onto said threaded portion of said coupling leg.

38. The connector fitting of claim 24, wherein the connector fitting is molded.

39. The connector fitting of claim 24, wherein the connector fitting is machined.

40. The connector fitting of claim 24, wherein the connector fitting is made from at least one of perfluoroalkoxy alkane (PFA), ethylene tetrafluoroethylene (ETFE), and fluorinated ethylene propylene (FEP).

41. A wrench for use with fittings used in fluid handling systems comprising:
a body,
at least two pins extending perpendicularly from the body, the pins dimensioned and configured to mate with at least two tubular portions disposed on the body of a fluid handling fitting.

42. The wrench of claim 41, wherein the wrench has two opposing legs perpendicular to the body and the pins are opposingly distributed on the legs, dimensioned and configured to mate with at least one tubular portion on the fitting.

43. A wrench for use with fittings used in fluid handling systems comprising:
a body,
at least two opposing legs extending perpendicularly from the body, the legs comprising a first leg and a second leg dimensioned and configured such that the first leg is configured to engage a first end of a first spacer and the first end of a second spacer and the second leg is configured to engage the second end of the first spacer and the second end of the second spacer, said first spacer and said second spacer being disposed on the neck portion of a connector fitting.
